(19) United States
(12) Patent Application Publication
(10) Pub. No.: US 2015/0201725 A1
(43) Pub. Date: Jul. 23, 2015

(54) Hook for Use With a Handbag to Locate Articles

(71) Applicant: GLOBAL SHOPPING NETWORK PTY LTD, Bondi Junction (AU)

(72) Inventor: Stephane Kljajic, North Bondi (AU)

(21) Appl. No.: 14/418,713

(22) PCT Filed: Feb. 20, 2013
(86) PCT No.: PCT/AU2013/000151

§ 371 Date: Jan. 30, 2015

(30) Foreign Application Priority Data
Feb. 20, 2012 (AU) 2012900614

(51) Int. Cl. A45C 13/00; H05K 5/02; F16M 13/02; A44B 15/00

(52) U.S. Cl. CPC A45C 13/001; A44B 15/00; H05K 5/0204; F16M 13/02

(57) ABSTRACT

A hook for detachable engagement with the interior of a bag, preferably a handbag, the hook preferably including a main body with a catch located on either end, the first of which is used to attach the hook to the bag itself and the second for hanging articles from. The first end further includes a retainer at the opening end of the hook to substantially close the hook so as to inhibit removal of the hook from the bag.

### STATEMENT OF RELATED APPLICATIONS

This application is a continuation of and claims priority from PCT application PCT/AU/2013/000151 filed Feb. 20, 2013, which in turn claims priority from Australian application 2012900614, filed Feb. 20, 2012.

### Field of the invention

The invention relates generally to a locator suitable for detachable mounting to a wall edge of a handbag, purse or other suitable wall.

### BACKGROUND OF THE INVENTION

Handbags and purses have a void that can be deep and large, and a plurality of items may be stored therein. However, searching for and retrieving a selected one of the plurality of items within a short time is often difficult. This is particularly true the more items stored within the handbag, the longer the handbag has been in use, and the deeper and larger the handbag.

A ring of keys is an item which is in regular use, and when the ring is deposited into the handbag, it can be difficult to find again for use when again required.

Some handbags have integral key holders but these must be sewn into walls of the handbag during manufacture which adds cost to the handbag and can interfere with the structural integrity of the wall, and cause the wall to buckle in an unintended position. Also the integral hooks that are known must be operated with two hands.

The present invention provides a user with a new locator.

In this specification, where a document, act or item of knowledge is referred to or discussed, this reference or discussion is not an admission that the document, act or item of knowledge or any combination thereof was at the priority date:
part of common general knowledge; or
known to be relevant to an attempt to solve any problem with which this specification is concerned.

### SUMMARY OF THE INVENTION

In a broad form the invention provides a locator suitable for locating articles disposed within a handbag for quick location and easy removal from the handbag. Preferably the removal of the articles from the handbag is single-handed and the arrangement is such that if any articles are attached to the locator, then during the removal of the articles from the locator, the removal of the locator from the handbag is inhibited.

According to one form of the invention a locator is provided for detachable engagement with a structure and hanging one or more articles therefrom, the locator including:
a main hanger body which includes a first catch and a second catch, the first and second catches being connected to one another;
wherein the first catch includes a first hook comprising a first retainer disposed at an opening region of the hook to substantially close the hook so as to inhibit removal of the first catch from the structure, and
the second catch being provided for hanging articles therefrom.

Preferably the first hook includes a curved arm in the form of a bight which extends to a neck region and the first retainer includes one or more bosses extending from a wall of the hook in the neck region to facilitate substantially closing the hook.

Preferably the boss is in the form of a triangular prism to facilitate substantially closing the hook, wherein a point of the triangular prism abuts an opposite wall of the curved arm at the neck region and the walls of the triangular prism facilitate inhibiting the removal of the first catch from the structure by providing a steep ramp. The front wall of the triangular prism also provides a steep ramp upon mounting of the hook to the structure, to provide a resistance to the user. The boss may be in the form of a hemispherical bump.

Preferably the second catch is in the form of a second hook which includes a curved arm in the form of a bight which extends to a neck region, wherein the neck region substantially closes the bight so as to be adapted to detachably engage with a ring of keys so that, when in use, the gate inhibits their inadvertent removal from the catch. A gate may be provided which closes the bight.

Preferably the gate includes a hinge to swing the gate between a closed position and an open position. Preferably the hinge includes a biasing means to bias the gate towards the closed position.

Preferably the first catch is disposed on a first side of the main hanger body and the second catch is disposed on a second side of the main hanger body. Preferably a proximal arm of the first catch is attached to a proximal arm of the second catch, so that the first catch opens on one side of the main hanger body and the second catch opens on the second side of the main hanger body, to facilitate single-handed removal of the keys from the second catch.

Preferably an elongate element is attached to the first and second proximal arms and extends therebetween. Preferably the elongate element is a spine.

The arrangement of the neck regions is preferably such that the retention force required to remove articles from the second catch is lower than the retention force required to remove the locator from the handbag. Thus, in use, the locator is more likely to stay on the handbag when articles are removed from the locator.

Preferably the gate when provided, or the arm in the region of the neck of the second catch includes an entry ramp or flare so that a set of keys may be guided into the second catch. Preferably the retention force on the gate or the neck region closing the second catch is lower than the retention force closing or retaining the first catch onto the structure so that removing an article from inside the second catch only removes the article from the second catch and not the first catch from the structure. Preferably the gate and the arm in the region of the neck returns to the neck at a lower angle to the proximal arm of the second catch than the angle of the walls of the triangular prism or bump walls to the proximal arm of the first catch so that an article slides off the second catch and the first catch is retained on the structure.

Preferably the first and second catches are integral with one another such that they are formed from one piece of material to reduce manufacturing costs. Preferably the material is spring steel.

Preferably a light is attached to the main hanger body. Preferably a beam of light from the light when in use is directed towards the second catch. Preferably the light is disposed on the elongate element on the reverse side of the first catch.

Preferably a decoration is disposed on the main hanger body. Preferably the decoration is disposed on the first catch, on an outer wall of the bight, on a second arm of the first catch. Preferably the decoration is in the form of a beaded medallion.

Preferably the first catch is a hinged catch which is in the form of a bi-stable hinge. It is to be understood that a type of bi-stable hinge is a lady's earring. In that kind of bi-stable hinge such as in this optional embodiment of the present invention, the first catch includes a biasing means that biases the proximal and distal arms of the first catch to close the neck when the arms are adjacent one another, on one side of an inflexion point. When the proximal and distal arms of the first catch are opened to the other side of the inflexion point, the biasing means biases the arms to an open position and holds them in that position.

Preferably the second catch includes a cradle. Preferably the cradle is suitable for removably cradling an electronic device such as a cellular telephone or smartphone.

Preferably the cradle is attached to the spine of the main hanger body. Preferably the cradle includes a cradle frame for mounting cradle elements thereon, the cradle frame connected to the spine.

The cradle elements include expansible cradle arms. Preferably a first cradle arm is for cradling a base of the electronic device. The first cradle arm may pivot or otherwise swing into an extended position. Preferably though, the first cradle arm is adapted to reciprocate longitudinally to move between an extended position in which the arm extends below the cradle frame so that the electronic device may be supported wholly or substantially below the top of the handbag or structure, out of sight, and a retracted position in which the arm is disposed at an elevated position to free up space within the handbag and to reduce the signature of the cradle if the handbag were to fold up. The first cradle arm includes a biasing means to bias the first cradle arm into the retracted position.

Also provided are second and third cradle arms. These cradle arms may be fixed to provide a cradle for a selected width of electronic device or phone, however, preferably the second and third cradle arms are expansible. Preferably the second and third cradle arms are adjustable. Preferably the adjustability is by hinges, pivots or other swing methods, but preferably the adjustability is by reciprocating arms into an extended position and a retracted position. Preferably the arms are linked together to facilitate single-handed operation.

Preferably the second and third arms are linked together by a rack and pinion so that an extension of the second or third arm results in an extension of the other of the two arms. Preferably a detent means is provided to retain the second and third arms in a selected extended position or retracted position. Preferably the detent means is a biased ball which is in the form of a spring-loaded ball which extends into selected recesses spaced apart and disposed along one of the second or third arms.

Preferably the first, second and third arms are linked together to facilitate single-handed operation by a rack and pinion or other similar device.

According to another preferred form of the invention there is provided a handbag having spaced-apart side walls, an opening at an upper edge of the side walls and a void within the handbag suitable for storing objects when in use, the handbag including a locator, the locator disposed within the void and including a main hanger body including an upper portion affixed to the side walls and a catch including a hook element which is in the form of a curved arm forming a bight, wherein a retainer in a neck region substantially closes the bight so as to be adapted to detachably engage with a ring of keys to, when in use, inhibit their removal from the catch.

According to yet another aspect of the present invention there is provided a locator suitable for locating articles within a handbag, the locator including a main locating body including:
a first catch, the first catch including a hook element which is in the form of an arm curved into a bight, wherein a first retainer in a neck region substantially closes the bight so as to be adapted to detachably engage with a structure in the handbag so as to, when in use, inhibit removal of the first catch from the structure, and
a light disposed on the main locating body and arranged so as to, when in operation, direct a beam of light into the handbag.

It is to be understood that although there are several distinct aspects of the invention defined individually herein, they may be combined with one another so that optional aspects of the invention may be provided in combination with any one aspect hereindefined and described.

### BRIEF DESCRIPTION OF THE DRAWINGS

To assist with understanding, the invention will now be explained with reference to preferred embodiments illustrated in the accompanying drawings in which:

FIG. 1 is a side elevation view of a locator in the form of a hanger according to a preferred embodiment of the invention, the hanger having a second catch and that catch being in a closed position;

FIG. 2 is a side elevation view of the locator of FIG. 1 with the catch being in an open position;

FIG. 3 is a front elevation view of the locator of FIG. 1;

FIG. 4 is a front elevation view of a locator having a different arrangement than that shown in FIG. 1, the locator having a light attached thereto and having only a first catch;

FIG. 5 is a side elevation view of the locator of FIG. 1 shown with a light;

FIG. 6 is a front elevation view of a locator of another embodiment of the present invention, shown in position on a handbag, with a decoration being disposed on the locator;

FIG. 7 is a rear elevation view of a locator of yet another embodiment of the present invention, the embodiment including a cradle having adjustable cradle arms for receiving varying sizes of electronic devices, including smartphones, the locator shown with a smartphone in the cradle, the smartphone shown in outline for clarity;

FIGS. 8 and 9 are rear elevation views of locators similar to those shown in FIG. 7; and

FIG. 10 is a side elevation view of another locator produced in accordance with a preferred embodiment of the present invention, the locator of this embodiment having a second catch with integral spring steel and no hinged gate.

### DETAILED DESCRIPTION OF PREFERRED EMBODIMENTS

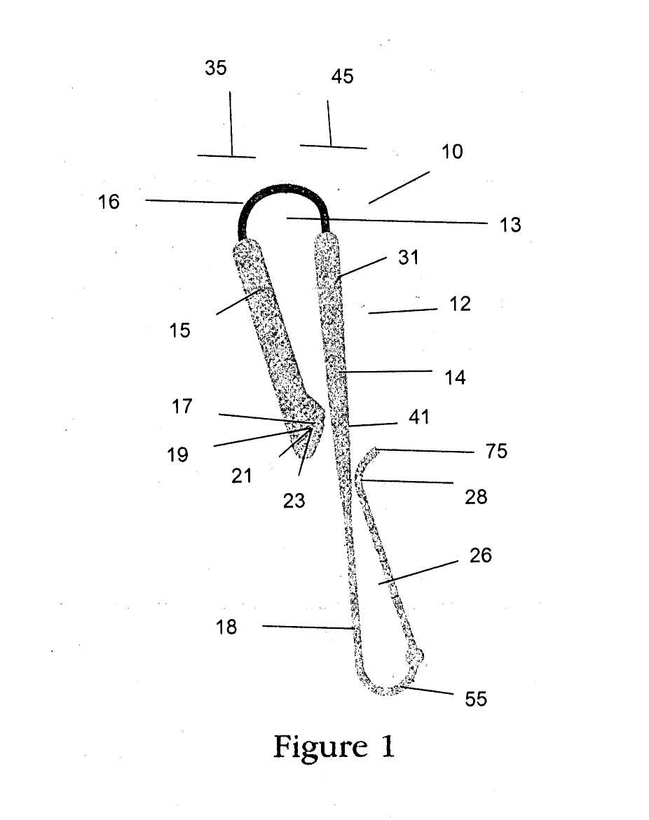

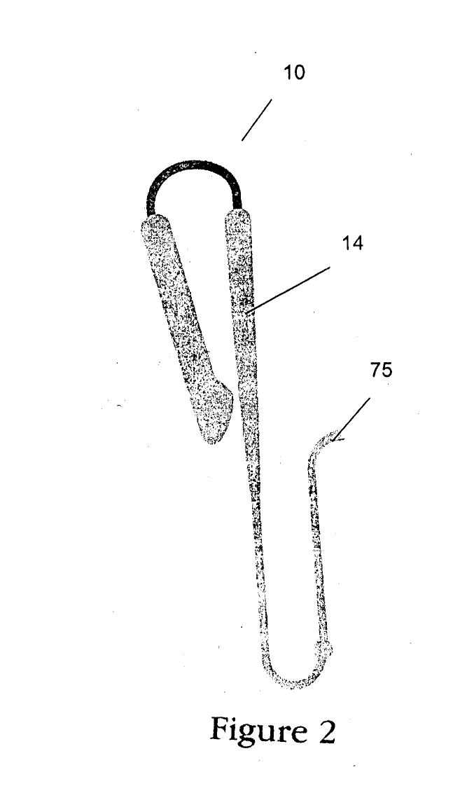

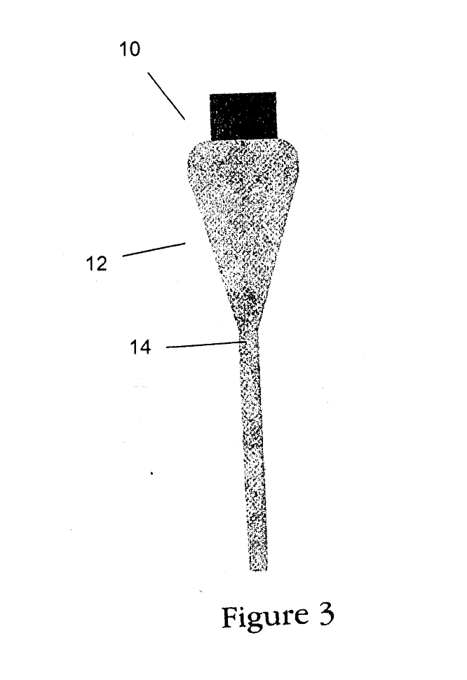

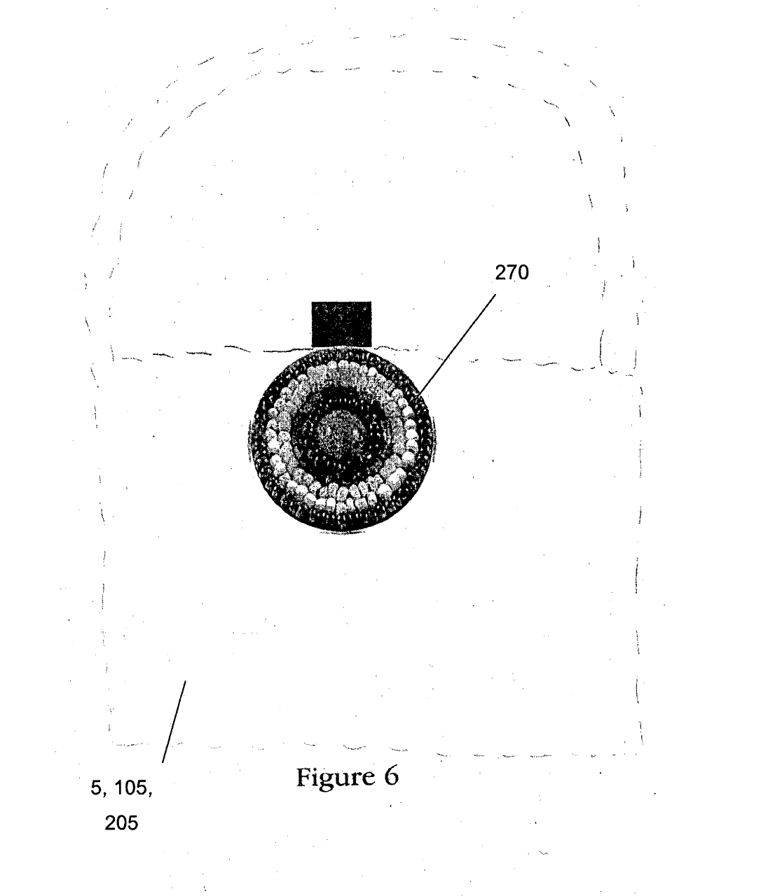

Referring to FIGS. 1 to 3 there is shown a locator for detachable engagement with a structure in the form of a handbag (shown as item 5 in FIG. 6), the locator generally indicated at 10. The locator 10 is for hanging one or more articles (not shown) therefrom, the locator 10 being in the form of a hanger 12 and including a main body 14 which includes a first catch 16 and a second catch 18, a portion of the first catch 16 and a portion of the second catch 18 being operatively connected to one another, wherein the first catch 16 includes a hook element 15 which is in the form of a curved arm in the form of a bight 13, wherein a first retainer 17 substantially closes the bight 13 so as to be adapted to detachably engage with the structure 5 so as to, when in use, inhibit removal of the first catch 16 from the structure 5, the second catch 18 being provided for hanging articles therefrom. The articles intended to be hung from the second catch 18 are rings of keys (not shown), and other items which are desired to be obtained quickly and not tainted or scratched by items in the bottom of the handbag 5.

The retainer 17 includes one or more bosses 21 extending from a first wall 22 of the bight 13 in the neck region 19. The one or more bosses 21 are in the form of a triangular prism 23 or a more rounded bump.

The second catch 18 includes a hook element 24 which is in the form of a bight 26, wherein a second retainer 28 in the form of a gate 29 substantially closes the bight 26 so as to be adapted to detachably engage with a ring of keys (not shown) to, when in use, inhibit their removal from the catch 18. A flare or ramp 75 is provided to facilitate the loading of a keyring in the catch 18.

The first catch 16 is disposed on a first side 35 of the main hanger body 14 and the second catch is disposed on a second side 45 of the main hanger body 14. A proximal arm 31 of the first catch 16 is attached to a proximal arm 41 of the second catch 18, the arrangement being such that an elongate element 50 or spine is attached to the first and second proximal arms and extends therebetween.

The first and second catches 16, 18 are integral with one another such that they are formed from one piece of material, and the material is spring steel 55.

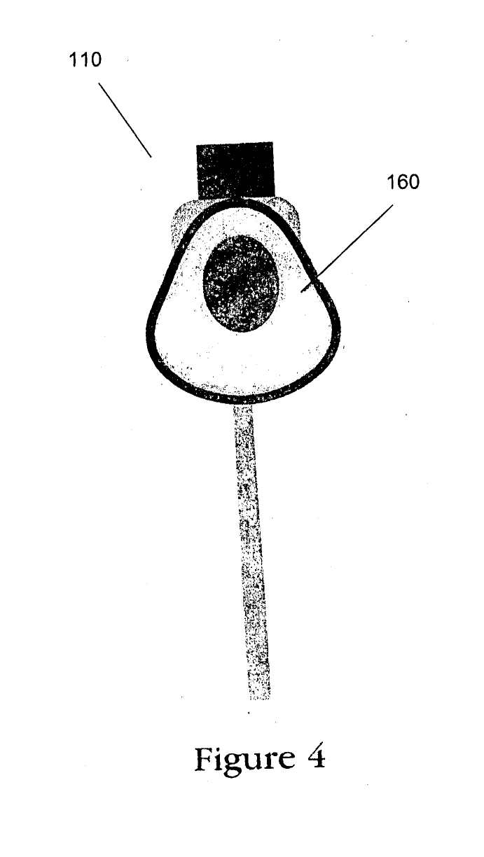

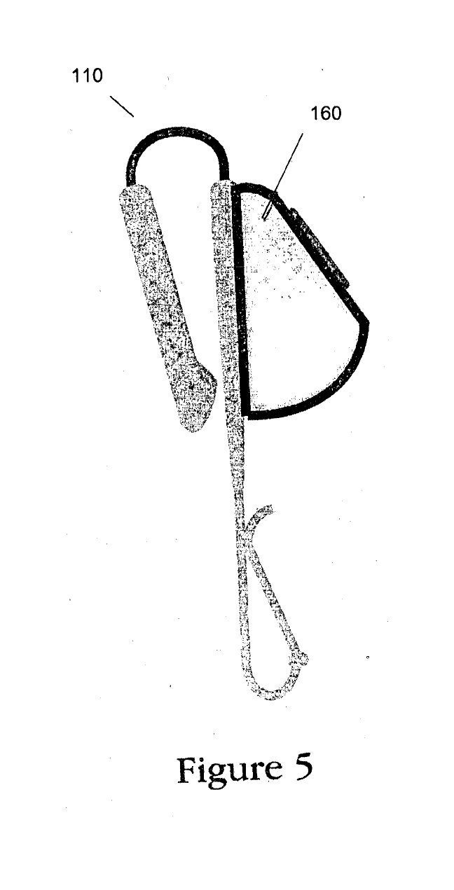

Another two embodiments, shown in FIGS. 4 and 5, will hereinafter be described. In the Figure and the description, like numerals denote like parts and this description will hereinafter focus on the portions not described above.

A light 160 is attached to the main hanger body 114. A beam of light from the light 160 when in use is directed towards the second catch 118 (only present and shown in FIG. 5—in the embodiment shown in FIG. 4 the second catch is not present). The light 160 is disposed on the elongate element 150.

Another embodiment is shown in FIG. 6, wherein a decoration 270 is disposed on the main hanger body 214. Optionally the decoration 270 is disposed on the first catch 216, on an outer wall of the bight 213, on a second arm of the first catch 216. The decoration 270 is in the form of a beaded medallion and in use is disposed on the outer wall of the handbag 205.

In use one embodiment of the locator is intended to hang articles such as keys in a second catch 18 from an upper edge of a handbag 5 so that they can be readily found and removed from the second catch 18, the latter action preferably with one hand. Other embodiments readily locate and identify a light for illuminating the inside of a handbag for locating articles such as keys inside the bag. The neck region of embodiments is intended to inhibit the removal of the locator from the handbag 5.

When the user removes the ring of keys from the catch 18, the retainer 17 inhibits the removal of the locator from the handbag 5. The arrangement of the retainers in the preferred embodiments shown is such that the retention force required to remove articles from the second catch is lower than the retention force required to remove the locator from the handbag. This is because of the relative holding forces between the first and second hooks as well as the relative angle of the walls on the triangular prism 23 and the gate 29. Thus, in use, the locator is more likely to stay on the handbag when articles are removed from the locator.

Also in use, to store the ring of keys on the catch 18, the force required is low and the action is fast, facilitated by the flare or ramp 75.

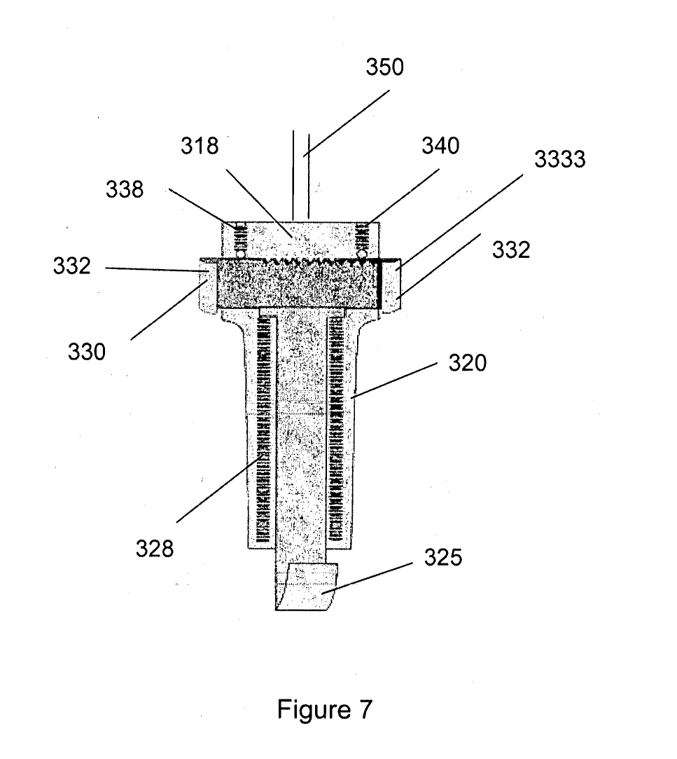

In some preferred embodiments of the present invention, the second catch 18 is in the form of a cradle 318. This embodiment is shown in FIGS. 7 to 9. The cradle 318 is suitable for removably cradling an electronic device such as a cellular telephone or smartphone 319.

The cradle 318 is attached to a spine 350 of the main body or a proximal arm of the first catch and the cradle includes a cradle frame 320 for mounting cradle elements 322 thereon, the cradle frame 320 connected to the spine 350.

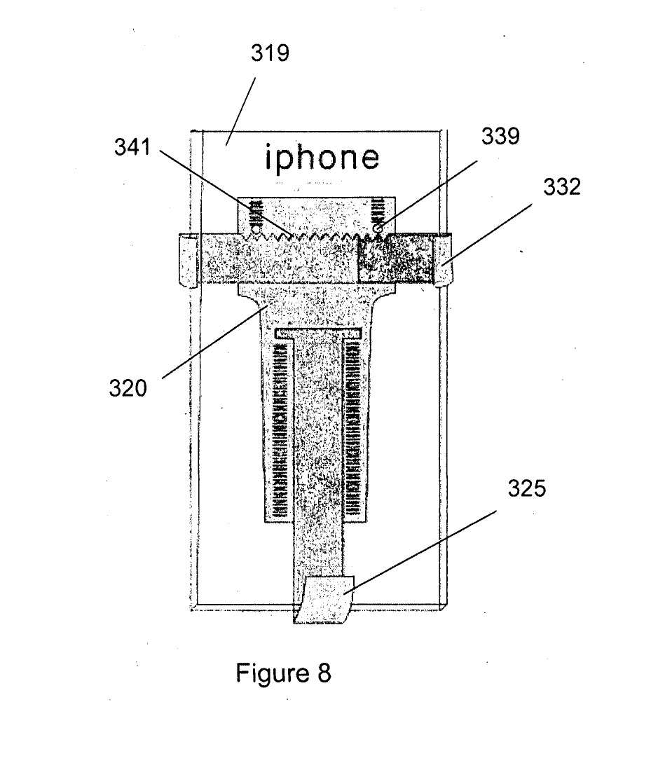

The cradle elements include expansible cradle arms 325. A first cradle arm 326 is for cradling a base of the electronic device 319. The first cradle arm 326 may pivot or otherwise swing into an extended position. Preferably though, the first cradle arm 326 is adapted to reciprocate longitudinally to move between an extended position (FIG. 8) in which the arm extends below the cradle frame so that the electronic device 319 may be supported wholly or substantially below the top of the handbag or structure, out of sight, and a retracted position (FIG. 7) in which the first cradle arm 326 arm is disposed at an elevated position to free up space within the handbag and to reduce the volume or signature of the cradle 318 if the handbag were to fold up. The first cradle arm includes a biasing means 328 to bias the first cradle arm into the retracted position.

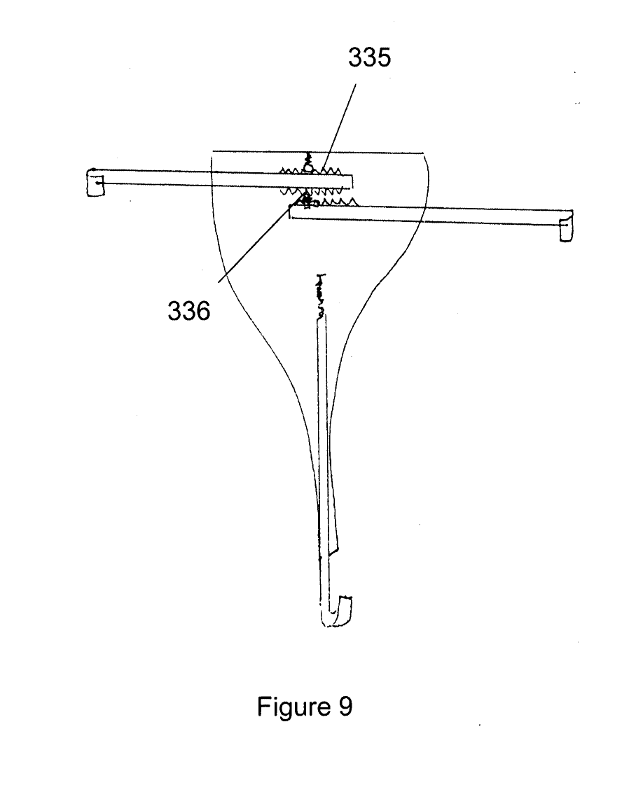

Also provided are second and third cradle arms 330, 332. These cradle arms 330, 332 may be fixed to provide a cradle for a selected width of electronic device or phone. However, preferably the second and third cradle arms 330, 332 are expansible as shown in FIGS. 7, 8 and 9. That is, the second and third cradle arms 330, 332 are adjustable. Optionally the adjustability is by hinges, pivots or other swing methods, but preferably, as shown in the Figures, adjustability is by reciprocating arms 331, 333 into an extended position and a retracted position. The arms are linked together in FIG. 9 to facilitate single-handed operation.

The second and third arms 330, 332 in the embodiment shown in FIG. 9 are linked together by a rack 335 and pinion 336 so that an extension of the second or third arm results in an extension of the other of the two arms. Preferably a detent means 338 is provided to retain the second and third arms in a selected extended position or retracted position. Preferably the detent means 338 is one or more biased balls 339 each of which is in the form of a spring-loaded ball 340 which extends into selected recesses 341 spaced apart and disposed along one of the second or third arms 330, 332.

Operation of the cradle is such that the operator opens up the arms 330, 332 with their hand and slides the phone 319 into the cradle. The weight of the phone 319 is sufficient to automatically extend the first cradle arm 325 into the extended position, against the biasing force of the spring or biasing means 328. Some embodiments such as those shown in FIGS. 7 and 8 have two detent mechanisms, one for each second and third arm 330, 332. These arms in these embodiments are not linked to one another by a linking mechanism such as that shown in FIG. 9, but they may be if convenient.

If a user wants to withdraw the phone from the purse, they lift the phone and the cradle arms retract under the influence of the springs (including those which may be biasing the second and third arms to the retracted position). The locator remains on the purse since the first catch is held more strongly onto the purse than the cradle holds the phone.

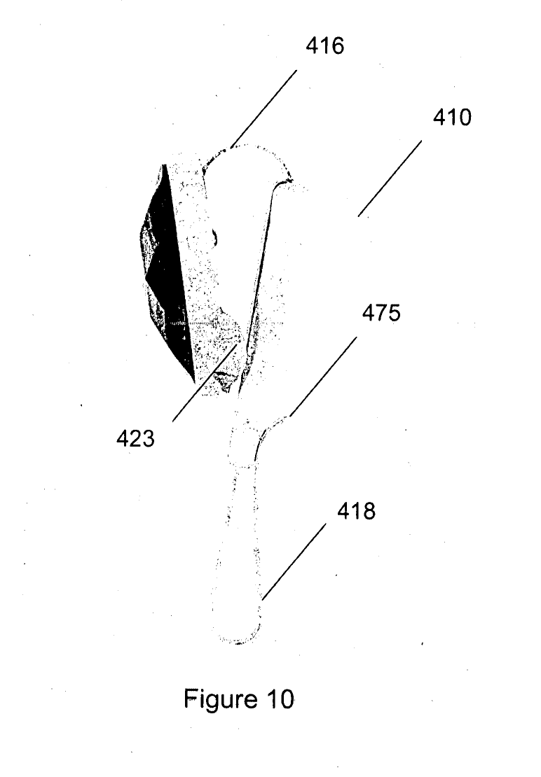

Yet another embodiment of the present invention is shown in FIG. 10. In this embodiment, very similar in almost every way to those shown in FIGS. 1 to 3 and 5 to 6, there is no pivoting gate in the second catch 418. The second catch 418 is a single piece of spring steel 420 which includes a flare 475 and is less strong in holding elements hanging thereon than the first catch. This relatively lower strength is present at least partly because of the flare 475 on the second catch being a lower angle than the bump 423 in the first catch 416 which improves retention of the bag wall by the first catch 416. There may also be a lower holding strength in the second catch relative to the first catch. This can be seen in the deeper loop traversed by the first catch 416.

In operation of the locator with the light, the user merely actuates the light with an actuator and shines a light beam into the purse to locate a selected item.

It is to be understood that although there are several distinct aspects of the invention defined individually herein, they may be combined with one another so that optional aspects of the invention may be provided in combination with any one aspect hereindefined and described.

The word ‘comprising’ and forms of the word ‘comprising’ as used in this description do not limit the invention claimed to exclude any variants or additions.

Modifications and improvements to the invention will be readily apparent to those skilled in the art. Such modifications and improvements are intended to be within the scope of this invention.

1. A locator for detachable engagement with a structure and hanging one or more articles therefrom, the locator including:
a main hanger body which includes a first catch and a second catch, the first and second catches being connected to one another;
wherein the first catch includes a first hook comprising a first retainer disposed at an opening region of the hook to substantially close the hook, so as to inhibit removal of the first catch from the structure, and
the second catch being provided for hanging articles.

2. The locator in accordance with claim 1 wherein the first hook includes a curved arm in the form of a bight which extends to a neck region and the first retainer includes one or more bosses extending from a wall of the hook in the neck region to facilitate substantially closing the hook.

3. The locator in accordance with claim 2 wherein the boss is in the form of a hemispherical bump to facilitate substantially closing the hook, wherein a point of the hemispherical bump abuts an opposite wall of the curved arm at the neck region and the walls of the triangular prism facilitate inhibiting the removal of the first catch from the structure by providing a steep ramp.

4. The locator in accordance with claim 3 wherein the second catch is in the form of a second hook which includes a curved arm in the form of a bight which extends to a neck region to substantially close the bight so as to be adapted to detachably engage with a ring of keys so that, when in use, the neck region inhibits their inadvertent removal from the [symbol] .

5. The locator in accordance with any one of claims 1 to 4 wherein the first catch is disposed on a first side of the main hanger body and the second catch is disposed on a second side of the main hanger body.

6. The locator in accordance with any one of claims 1 to 5 wherein a proximal arm of the first catch is attached to a proximal arm of the second catch, so that the first catch opens on one side of the main hanger body and the second catch opens on the second side of the main hanger body, to facilitate single-handed removal of the keys from the second catch.

7. The locator in accordance with claim 6 wherein an elongate element is attached to the first and second proximal arms and extends therebetween, the elongate element being in the form of a spine.

8. The locator in accordance with any one of claims 2 to 7 wherein the arrangement of the neck regions is preferably such that a retention force required to remove articles from the second catch is lower than a retention force required to remove the locator from the handbag so that in use, the locator is more likely to stay on the handbag when articles are removed from the second catch.

9. The locator in accordance with any one of claims 1 to 8 wherein the second catch includes an entry ramp so that a set of keys may be guided into the second catch.

10. The locator in accordance with any one of claims 2 to 9 wherein a retention force on the neck region closing the second catch is lower than a retention force closing or retaining the first catch onto the structure so that removing an article from inside the second catch only removes the article from the second catch and not the first catch from the structure.

11. The locator in accordance with any one of claims 1 to 10 wherein a light is attached to the main hanger body.

12. The locator in accordance with claim 10 wherein a beam of light from the light when in use is directed towards the second catch.

13. The locator in accordance with any one of claims 1 to 12 wherein the first catch is a hinged catch which is in the form of a bi-stable hinge.

14. The locator in accordance with any one of claims 1 to 13 wherein the second catch includes a cradle suitable for removably cradling an electronic device such as a cellular telephone or smartphone.

15. The locator in accordance with claim 14 wherein the cradle is attached to the spine of the main body.

16. The locator in accordance with claim 14 or 16 wherein the cradle includes a cradle frame for mounting a plurality of cradle elements thereon, the cradle frame connected to the spine.

17. The locator in accordance with claim 16 wherein the plurality of cradle elements include expansible cradle arms.

18. The locator in accordance with claim 17 wherein a first expansible cradle arm is for cradling a base of the electronic device.

19. The locator in accordance with claim 17 or 18 wherein the first expansible cradle arm is adapted to pivot or otherwise swing into an extended position.

20. The locator in accordance with claim 17 or 18 wherein the first expansible cradle arm is adapted to reciprocate longitudinally to move between an extended position in which the first expansible cradle arm extends below the cradle frame so that the electronic device may be supported wholly or substantially below the top of the handbag or structure, out of sight, and a retracted position when the phone is not disposed in the cradle in which the first expansible cradle arm is disposed at an elevated position to free up space within the handbag and to reduce the signature of the cradle if the handbag were to fold up.

21. The locator in accordance with any one of claims 17 to 20 wherein the first expansible cradle arm includes a biasing means to bias the first expansible cradle arm into the retracted position.

22. The locator in accordance with any one of claims 17 to 21 wherein the cradle arms include second and third cradle arms which are expansible to accommodate varying widths of electronic device.

23. The locator in accordance with claim 22 wherein the second and third cradle arms are linked together to facilitate single-handed operation and are linked together by a rack and pinion so that an extension of the second or third arm results in an extension of the other of the two arms.

24. The locator in accordance with claim 22 or 23 wherein a detent means is provided to retain the second and third arms in a selected extended position or retracted position.

25. The locator in accordance with claim 24 wherein the detent means is a biased ball which is in the form of a spring-loaded ball which extends into selected recesses spaced apart and disposed along one of the second or third arms.
